(19) United States
(12) Patent Application Publication
(10) Pub. No.: US 2005/0022855 A1
(43) Pub. Date: Feb. 3, 2005

(54) Thermoelectric power generator for a gas turbine engine

(76) Inventor: Bernard J. Raver, Ellington, CT (US)

Correspondence Address: BACHMAN & LAPOINTE, P.C., 900 CHAPEL STREET, SUITE 1201, NEW HAVEN, CT, 06510, US

(21) Appl. No.: 10/631,440

(22) Filed: Jul. 30, 2003

(51) Int. Cl. H01L 37/00

(52) U.S. Cl. 136/205; 136/201

(57) ABSTRACT

A method for generating electricity from an engine comprising the steps of depositing a plurality of alternating portions of an N-type material and a P-type material in series on an engine component, and providing an electrically conductive material between each of two adjoining portions of the N-type material and the P-type material to form a circuit.

### BACKGROUND OF THE INVENTION

(1) Field of the Invention

The present invention relates to a method of generating electricity from the thermal energy produced in a gas turbine engine.

(2) Description of Related Art

Engines mounted in aircraft, particularly gas turbine engines, typically generate a great deal of heat. The excessive generation of heat can lead to engine failure. In other instances, such as in stealth aircraft, there is a need to dissipate exhaust heat so as to maintain concealment. In addition, modern avionics and weapon systems place an increased demand for electricity on the aircraft.

What is therefore needed is a method for removing and dissipating the heat generated by a gas turbine engine in an aircraft as well as a method for increasing the generation of electricity. Most preferable would be to devise a method whereby the heat generated in a gas turbine engine can be converted into electricity.

### SUMMARY OF THE INVENTION

Accordingly, it is an object of the present invention to provide a method of generating electricity from the thermal energy produced in a gas turbine engine.

It is a further object of the present invention to provide a method for generating electricity from an engine which comprises the steps of depositing a plurality of alternating portions of an N-type material and a P-type material in series on an engine component, and providing an electrically conductive material between each of two adjoining portions of the N-type material and the P-type material to form a circuit.

It is a further object of the present invention to provide a method for generating electricity from an engine which comprises the steps of fabricating and arranging a plurality of alternating portions of an N-type material and a P-type material into an engine component in alternating fashion, and providing an electrically conductive material to connect each of the plurality of alternating portions of an N-type material and a P-type material in series.

It is a further object of the present invention to provide an engine which comprises at least one engine component comprising a plurality of alternating portions of an N-type material and a P-type material connected in series on an engine component via an electrically conductive material to form a circuit.

### BRIEF DESCRIPTION OF THE DRAWINGS

FIG. 1 is a diagram of the configuration of the P-type and N-type materials of the present invention.

FIG. 2 is a diagram showing the preferred placement of the P-type and N-type materials of the present invention.

### DETAILED DESCRIPTION OF THE PREFERRED EMBODIMENT(S)

It is therefore a central teaching of the present invention to provide a method for applying thermoelectric semiconductor material to the components of a gas turbine engine in order to produce electrical power. In addition, the present invention further enables one to provide electrical current to an operating gas turbine engine so as to quickly remove the heat produced therein.

The fundamental physical principles which form the basis for the present invention are described as follows. The Carnot cycle is associated with the efficiency of a thermoelectric device. The efficiency of the Carnot cycle is reduced by a factor which is dependent upon the thermoelectric figure of merit (ZT) of the materials used in fabrication of the thermoelectric device. The coupling between electrical and thermal effects in a material as defined by the dimensionless figure of merit (ZT) is represented as ZT=σS²T/K where σ is the electrical conductivity, S is the Seebeck coefficient, T is the absolute temperature, and K is the thermal conductivity.

The basic thermoelectric effects at issue in the present invention are the Seebeck and the Peltier effects. The Seebeck effect is the phenomena associated with the conversion of heat energy into electrical power where an induced voltage occurs in the presence of a temperature gradient. As such, the Seebeck effect may be used to generate electricity in the presence of a temperature differential. Conversely, the Peltier effect is a phenomena-whereby cooling/heating occurs in the presence of an electrical current through the junction of two dissimilar materials. As a result, the Peltier effect allows one to engage in cooling/thermal management of a material through the addition of electrical current at the junction of dissimilar materials, particularly P-type and N-type materials.

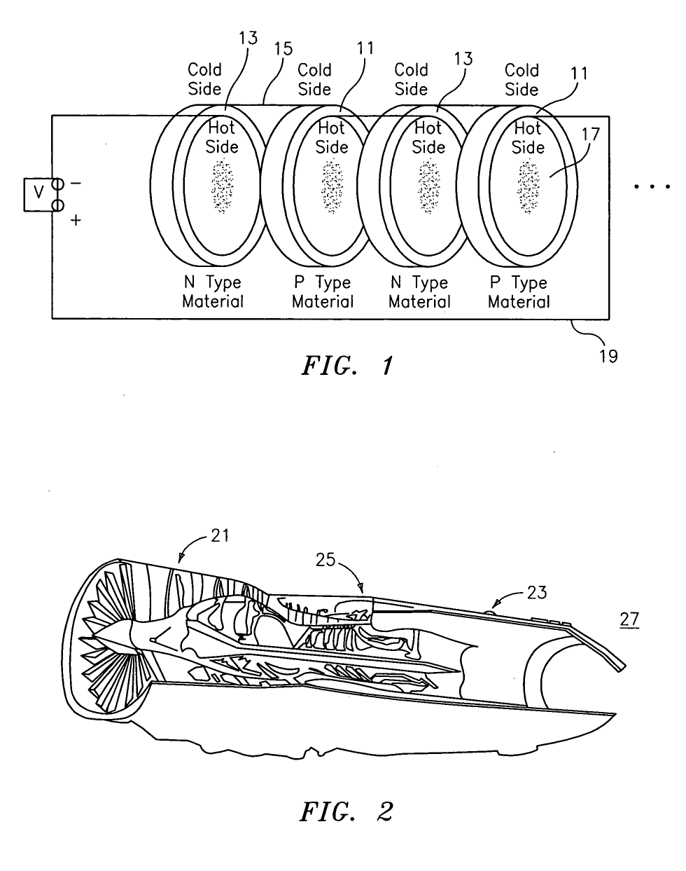

With reference to FIG. 1, there is illustrated the arrangement of P-type materials 11 and N-type materials 13 used to generate electric current from a gas turbine engine. As illustrated, the P-type material 11 and N-type materials 13 are formed into cylindrical rings and are connected in series in alternating fashion by a conductive material such as electric conductor 15. In the present example, both the N-type material 13 and the P-type material 11 are illustrated as generally cylindrical rings of material connected in series surrounding a heated interior 17. Although illustrated as rings of material, the actual configuration of N-type material 13 and P-type material 11 is not so limited. Rather, N-type material 13 and P-type material 11 may be of any configuration such that the materials 13, 11 are arranged in alternating fashion. In a preferred embodiment, N-type material 13 and P-type material 11 form continuous bands, or rings, which may be disposed around a heated interior 17 as illustrated.

As can be seen, each N-type material 13 or P-type material 11 is isolated from neighboring materials 13, 11 and is connected only through electric conductor 15. As a result of heated interior 17, each N-type material 13 and P-type material 11 has both a hot side and a cold side. The hot side corresponds to the side closer to the heated interior 17 and, conversely, the cold side corresponds to a side of either N-type material 13 or P-type material 11 located furthest from heated interior 17. The electric conductor 15 connects the cold side of each N-type material 13 to the cold side of a P-type material 11 while another electric conductor 15 connects the hot side of each P-type material 11 to the hot side of an N-type material 13. As a result, electrons gain energy from their surroundings as they move over the barrier at the NP junction. Heat is absorbed on the “hot” side of the N-type and P-type materials and is released on the cold side of the N-type and P-type materials. This gain in electron energy comprises the electrical current which then flows through exemplary circuit 19. Conversely, the process may be reversed, and a current may flow through exemplary circuit 19 so as to move heat away from the interior of N-type materials 13 and P-type materials 11, thus removing a portion of the energy created in heated interior 17.

With reference to FIG. 2, there is illustrated areas of a gas turbine engine 27 most suitably adapted to make use of the present invention. Specifically, fan case section 21, augmentor liner 23, and compressor 25 are ideally constructed to allow for the deposition of N-type material and P-type material in generally encircling bands, in alternating fashion, to generate electricity as described above. In addition to depositing N-type material 13 and P-type material 11 upon components comprising a gas turbine engine, N-type material 13 and P-type material 11 may alternatively be fabricated into the individual components. In such an instance, the N-type materials 13 and P-type materials 11 serve to provide both electricity and structural support for the components of the engine. Examples of N-type material 13 and P-type material 11 include, but are not limited to Si₁₋ₓGeₓ alloys, Skutterudites, and Co-based oxides.

As a result of either depositing upon or fabricating into the components of an engine N-type materials 13 and P-type materials 11, the heat energy of the engine may be used to generate electrical energy without the incorporation of moving parts. As a result, the present invention provides an environmental green methodology for generating electricity from engine heat which involves no compressed gases or chemicals. A turbofan engine, augmented to make use of the present invention, creates a substantial amount of thermal energy differentials. Specifically, such thermal differentials exist in areas between the inside and the outside of the augmentor liner and in the area around the outside of a combustor as noted above. The generation of thermal electric power as described above is well suited to operate in the hostile environments found in and around a gas turbine engine.

It is apparent that there has been provided in accordance with the present invention a method of generating electricity from the thermal energy produced in a gas turbine engine which fully satisfies the objects, means, and advantages set forth previously herein. While the present invention has been described in the context of specific embodiments thereof, other alternatives, modifications, and variations will become apparent to those skilled in the art having read the foregoing description. Accordingly, it is intended to embrace those alternatives, modifications, and variations as fall within the broad scope of the appended claims.

1. A method for generating electricity from an engine comprising the steps of:
depositing a plurality of alternating portions of an N-type material and a P-type material in series on an engine component; and
providing an electrically conductive material between each of two adjoining portions of said N-type material and said P-type material to form a circuit.

2. The method of claim 1 comprising the additional step of operating said engine to generate heat.

3. The method of claim 2 comprising the additional step of generating electricity from said generated heat.

4. The method of claim 2 comprising the additional step of passing an electrical current through said plurality of alternating portions of said N-type material and said P-type material to draw said generated heat from said engine.

5. The method of claim 1 wherein said engine comprises a turbofan engine.

6. The method of claim 1 wherein said engine component is selected from the group consisting of a fan case section, a combustor, and an augmentor liner.

7. The method of claim 1 wherein said depositing step comprises bonding said plurality of alternating portions of said N-type material and said P-type material to a surface of said engine component.

8. The method of claim 1 wherein said N-type materials are selected from the group consisting of Si₁₋ₓGeₓ alloys, Skutterudites, and Co-based oxides.

9. A method for generating electricity from an engine comprising the steps of:
fabricating and arranging a plurality of alternating portions of an N-type material and a P-type material into an engine component in alternating fashion; and
providing an electrically conductive material to connect each of said plurality of alternating portions of an N-type material and a P-type material in series.

10. The method of claim 9 comprising the additional step of operating said engine to generate heat.

11. The method of claim 10 comprising the additional step of generating electricity from said generated heat.

12. The method of claim 10 comprising the additional step of passing an electrical current through said plurality of alternating portions of said N-type material and said P-type material to draw said generated heat from said engine.

13. The method of claim 9 wherein said engine comprises a turbofan engine.

14. The method of claim 9 wherein said engine component is selected from the group consisting of a fan case section, a combustor, and an augmentor liner.

15. The method of claim 9 wherein said depositing step comprises bonding said plurality of alternating portions of said N-type material and said P-type material to a surface of said engine component.

16. The method of claim 9 wherein said N-type and said P-type materials are selected from the group consisting of Si₁₋ₓGeₓ alloys, Skutterudites, and Co-based oxides.

17. An engine comprising:
at least one engine component comprising a plurality of alternating portions of an N-type material and a P-type material connected in series on said engine component via an electrically conductive material to form a circuit.

18. The engine of claim 17 wherein said engine component is selected from the group consisting of a fan case section, a combustor, and an augmentor liner.

19. The engine of claim 17 wherein said plurality of alternating portions of an N-type material and a P-type material is deposited upon said engine component.

20. The engine of claim 17 wherein said plurality of alternating portions of an N-type material and a P-type material fabricated into said engine component

21. The method of claim 2 comprising the additional step of absorbing said generated heat from a heated interior of said engine by said N-type material and said P-type material.

22. The method of claim 21 comprising the additional step of releasing said absorbed heat of said N-type material and said P-type material through said electrically conductive material.

23. The method of claim 2 comprising the additional step of generating an electric current by absorbing generated heat from a heated interior of said engine by said N-type material and said P-type material and releasing said absorbed heat of said N-type material and said P-type material through said electrically conductive material.

24. The method of claim 19 comprising the additional step of generating an electric current by absorbing generated heat from a heated interior of said engine component by said N-type material and said P-type material and releasing said absorbed heat from said N-type material and said P-type material through said electrically conductive material.

25. The engine of claim 17 wherein said N-type material and said P-type material each possess a hot side and a cold side.

26. The engine of claim 25 wherein said hot side is closest to a heated interior of said at least one engine component.

27. The engine of claim 25 wherein said cold side is furthest from a heated interior of said at least one engine component.

28. The engine of claim 17 wherein said plurality of alternating portions of said N-type material and said P-type material are annular in shape.

29. The engine of claim 28 wherein said plurality of alternating portions of said N-type material and said P-type material are cylindrical rings connected in series in alternating fashion by said electrically conductive material.

30. The engine of claim 17 wherein said plurality of alternating portions of said N-type material and said P-type material are cylindrical rings surrounding a heated interior of said at least one engine component.
